(19) United States
(12) Patent Application Publication
(10) Pub. No.: US 2019/0252560 A1
(43) Pub. Date: Aug. 15, 2019

(54) COLORFUL THIN FILM SOLAR CELL FOR MINIMIZING REDUCTION OF EFFICIENCY

(71) Applicants: KOOKMIN UNIVERSITY INDUSTRY ACADEMY COOPERATION FOUNDATION, Seoul (KR); KOREA INSTITUTE OF SCIENCE AND TECHNOLOGY, Seoul (KR)

(72) Inventors: Young Rag Do, Seoul (KR); Chang Wook Kim, Seoul (KR); Ji Hye Oh, Gyeonggi-do (KR); Byoung Koun Min, Seoul (KR)

(21) Appl. No.: 15/906,415

(22) Filed: Feb. 27, 2018

(30) Foreign Application Priority Data
Feb. 13, 2018 (KR) 10-2018-0017996

(51) Int. Cl. H01L 31/0216; H01L 31/054

(52) U.S. Cl. CPC H01L 31/02167; H01L 31/0445; H01L 31/054

(57) ABSTRACT

The present invention provides a colored thin film solar cell capable of minimizing reduction of efficiency of a thin film solar cell and improving a utility value by visually changing a black color of the thin film solar cell into an aesthetically pleasing color to exhibit an exterior appearance, thereby facilitating commercialization of the thin film solar cell, and provides a method for manufacturing the same.

### CROSS-REFERENCE TO RELATED APPLICATION

This application claims priority to and the benefit of Korean Patent Application No. 10-2018-0017996, filed on Feb. 13, 2018, the disclosure of which is incorporated herein by reference in its entirety.

### BACKGROUND

### 1. Field of the Invention

The present invention relates to a colored thin film solar cell, and more particularly, to a colored thin film solar cell capable of minimizing reduction of efficiency of a thin film solar cell and improving a utility value by visually changing a black color of the thin film solar cell into an aesthetically pleasing color to exhibit an exterior appearance, thereby facilitating commercialization of the thin film solar cell.

### 2. Discussion of Related Art

In recent years, the use of photovoltaic power generation facilities capable of generating power using solar energy is becoming increasingly common. A solar cell using such solar energy utilizes sunlight, which is a clean and infinite energy source, instead of fossil fuel such as coal or petroleum, and thus it is getting attention as a new future alternative energy source and is presently used to obtain power in a solar power plant, a building, a vehicle, and the like.

There are various application fields in photovoltaic power generation, but among them a building integrated photovoltaic (BIPV) technique, in which a solar cell is employed as a finishing material of a building envelope, has recently attracted worldwide attention as a promising new technique in the 21st century. BIPV technique is an aggressive technique of developing a typical building envelope into a tool for generating energy by breaking from a point of view regarding a simple concept of protection against external stimuli, and thus a double effect of taking a part in supply and demand of solar cells and reducing costs for installation of conventional solar cell systems can be expected. One of the uses of solar cells as building exterior materials is as solar cell exterior in which a solar cell is coupled to windows and doors.

Regarding the solar cell exterior, Korean Registered Patent No. 10-1541357 discloses a thin film solar cell for application to the exterior and a method for manufacturing the same. However, there is a problem in that a typical thin film solar cell for application to the exterior has an exterior appearance exhibiting a black color resulting in lowering of a utility value for the exterior, thereby causing a difficulty in commercialization, and transmittance of sunlight is lowered such that efficiency of the typical thin film solar cell is reduced when a color converting filter is provided on an outer surface of the solar cell.

### RELATED ART DOCUMENT

(Patent Document 1) Korean Registered Patent No. 10-1541357

### SUMMARY OF THE INVENTION

The present invention is directed to a colored thin film solar cell capable of minimizing reduction of efficiency of a thin film solar cell and improving a utility value by visually changing a black color of the thin film solar cell into an aesthetically pleasing color to exhibit an exterior appearance, thereby facilitating commercialization of the thin film solar cell.

According to an aspect of the present invention, there is provided a colored thin film solar cell, which includes a solar cell, and a band-stop filter provided on one surface of the solar cell, configured to reflect a portion of externally emitted light and transmit the remaining portion thereof to thereby visually change a color of the solar cell and having a reflective band half width in a range of 100 nm or less.

The half width may be in a range of 70 nm or less.

The band-stop filter may be configured such that a first layer, a second layer, and a third layer are alternately stacked, and a repetition unit of the first-second-third layers is repeatedly stacked n times, a refractive index of the second layer may be different from that of the first layer, and a refractive index of the third layer may be equal to or different from that of the first layer.

The refractive index of each of the first layer and the third layer may be in a range of 1.2 to 1.6, and the refractive index of the second layer may be in a range of 1.4 to 1.8.

Each of the first layer and the third layer may include SiO₂, and the second layer may include Al₂O₃.

n may be in a range of 3 to 25.

The band-stop filter may visually change a color of the solar cell into one of a blue color, a green color, a yellow color, a purple color, and a red color.

The band-stop filter may have reflectance of 60% or more at a central reflection wavelength thereof.

The solar cell may be a perovskite solar cell, a copper indium gallium selenide (CIGS) solar cell, or a silicon solar cell.

According to another aspect of the present invention, there is provided a colored thin film solar cell, which includes a solar cell, and a band-stop filter provided on one surface of the solar cell, configured to reflect a portion of externally emitted light and transmit the remaining portion thereof to thereby visually change a color of the solar cell, wherein the colored thin film solar cell satisfies conditions (a) and (b):

(a) The band-stop filter has a reflective band half width in a range of 100 nm or less, and

(b) A relational expression 1 is satisfied as follows,

$$0.80 \leq \frac{A}{B} \leq 1.00$$

wherein, A is light harvesting efficiency when one or more band-stop filters, each having a reflective band half width in a range of 100 nm or less, are employed, and B is light harvesting efficiency when the one or more band-stop filters are not employed.

The colored thin film solar cell may further satisfy a condition (c):

(c) A relational expression 2 is satisfied as follows,

$$0.80 \leq \frac{C}{D} \leq 1.00 \qquad [ Relational Expression 2 ]$$

wherein C is a short circuit current density J_{sc} when the one or more band-stop filters, each having a reflective band half width in a range of 100 nm or less, are employed, and D is a short circuit current density J_{sc} when the one or more band-stop filters are not employed.

According to still another aspect of the present invention, there is provided an exterior including the colored thin film solar cell according to the present invention.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1A is a photograph of red, green, and blue band-stop filters;

FIG. 1B is a photograph of a colored thin film solar cell having the red, green, and blue band-stop filters;

FIG. 2A is a graph illustrating a transmittance spectrum of a green band-stop filter manufactured according to one embodiment of the present invention;

FIG. 2B is a graph illustrating a transmission spectrum of a blue band-stop filter manufactured according to one embodiment of the present invention;

FIG. 2C is a graph illustrating a transmittance spectrum of a red band-stop filter manufactured according to one embodiment of the present invention;

FIG. 2D is a graph illustrating a transmission spectrum of a red-dichroic filter;

FIG. 3A is a graph illustrating an external quantum efficiency (EQE) spectrum and a diffusive reflectance spectrum of a colored thin film solar cell having the green band-stop filter according to one embodiment of the present invention;

FIG. 3B is a graph illustrating an EQE spectrum and a diffusive reflectance spectrum of a colored thin film solar cell having the blue band-stop filter according to one embodiment of the present invention;

FIG. 3C is a graph illustrating an EQE spectrum and a diffusive reflectance spectrum of a colored thin film solar cell having the red band-stop filter according to one embodiment of the present invention;

FIG. 3D is a graph illustrating an EQE spectrum and a diffusive reflectance spectrum of a colored thin film solar cell having the red-dichroic filter;

FIG. 4 is a scanning electron microscope (SEM) cross-sectional images of the red, green, and blue band-stop filters manufactured according to one embodiment of the present invention;

FIG. 5A is a current-voltage graph of a colored thin film solar cell having the green band-stop filter according to one embodiment of the present invention;

FIG. 5B is a current-voltage graph of a colored thin film solar cell having the blue band-stop filter according to one embodiment of the present invention;

FIG. 5C is a current-voltage graph of a colored thin film solar cell having the red band-stop filter according to one embodiment of the present invention;

FIG. 5D is a current-voltage graph of a colored thin film solar cell having the red-dichroic filter.

FIG. 6 is a graph illustrating relative efficiency of a colored thin film solar cell according to one embodiment of the present invention; and

FIG. 7 is Commission Internationale de l'Eclairage (CIE) color coordinates of a colored thin film solar cell having red, green, and blue band-stop filters according to a preferred embodiment of the present invention.

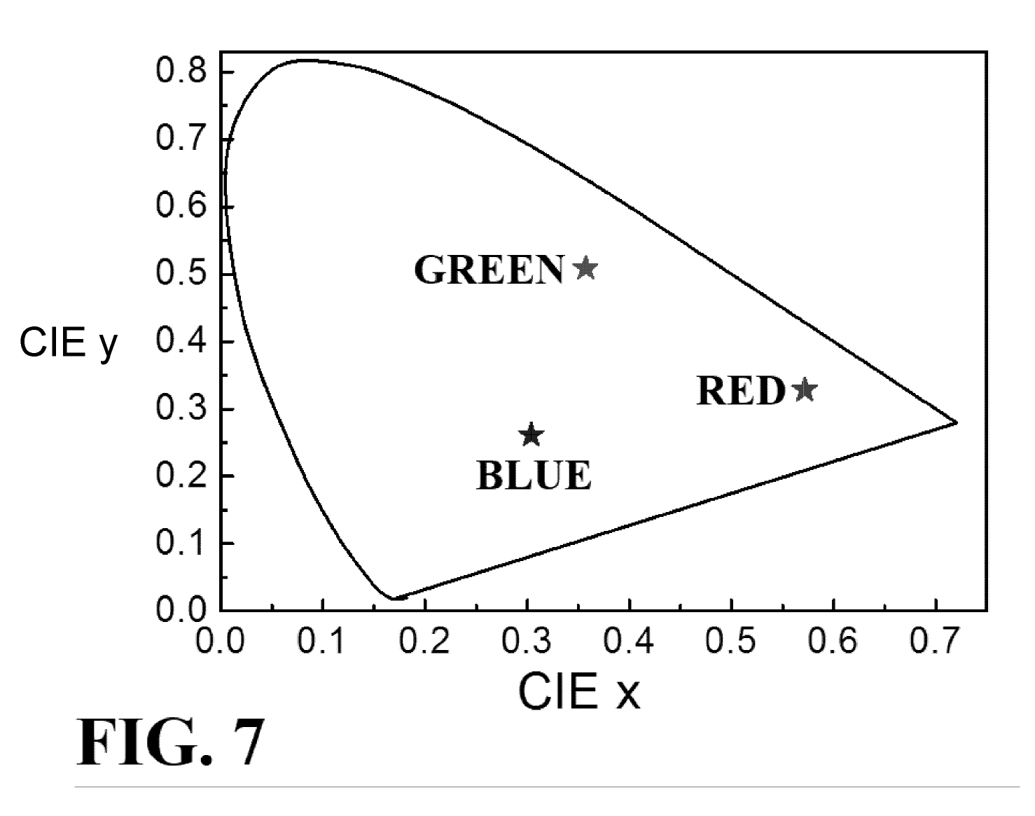

### DETAILED DESCRIPTION OF EXEMPLARY EMBODIMENTS

Hereinafter, embodiments of the present invention will be fully described in detail which is suitable for easy implementation by those skilled in the art with reference to the accompanying drawings.

As is described above, a conventional thin film solar cell for application to the exterior has outstanding stability and efficiency while having an exterior appearance of a black color, resulting in lowering of a utility value for the exterior, thereby causing a problem of difficulty in commercialization. That is, conventionally, there is a problem in that it is difficult to maintain efficiency required for a thin film solar cell while implementing a visual color change of the exterior appearance of the thin film solar cell.

To resolve the above-described problems, the present invention provides a colored thin film solar cell having a band-stop filter provided on one surface of a thin film solar cell, wherein the band-stop filter has a reflective band half width in a range of 100 nm or less and changes a color of the thin film solar cell by reflecting a portion of externally emitted light and transmitting the remaining portion thereof. With such a configuration, there is an effect in which a utility value for application to windows and doors or a building's outer walls or interior may be improved by visually changing a black color of the thin film solar cell into an aesthetically pleasing color, to exhibit an exterior appearance having the aesthetically pleasing color without a substantial reduction in efficiency of the thin film solar cell, thereby facilitating the commercialization of the colored thin film solar cell. Further, even when the colored thin film solar cell is used as a finishing material of a building envelope, the black color of the thin film solar cell can be visually changed into an aesthetically pleasing color with only a slight reduction in light harvesting efficiency and a short circuit current density J_{sc}, thereby being easily utilized in a building integrated photovoltaic (BIPV) technique field.

A band-stop filter employed in a colored thin film solar cell of the present invention will be described first.

The band-stop filter visually changes a color of a thin film solar cell by reflecting a portion of externally emitted light and transmitting the remaining portion thereof. The band-stop filter may implement various colors by controlling a wavelength within a reflective band.

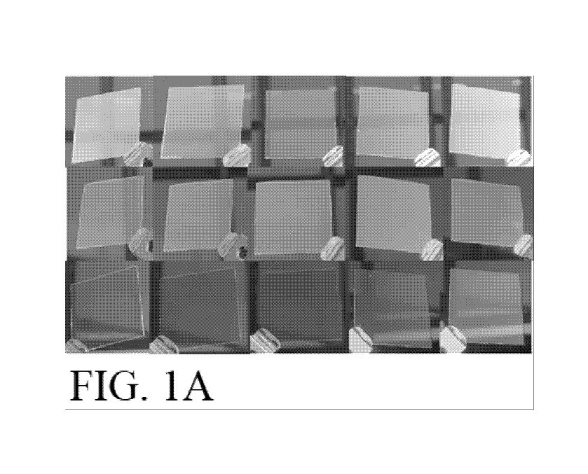

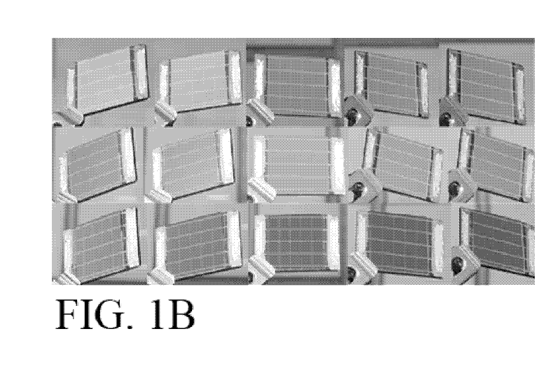

In this regard, FIGS. 1A and 1B are photographs of red, green, and blue band-stop filters which are manufactured according to one preferred embodiment of the present invention, and of a colored thin film solar cell having the same. Referring to FIGS. 1A and 1B, it can be seen that a color of a thin film solar cell is visually changed into an aesthetically pleasing color by employing the band-stop filters according to the present invention. Further, it can be seen that a distinct color of high purity may be exhibited in an extremely narrow reflective band.

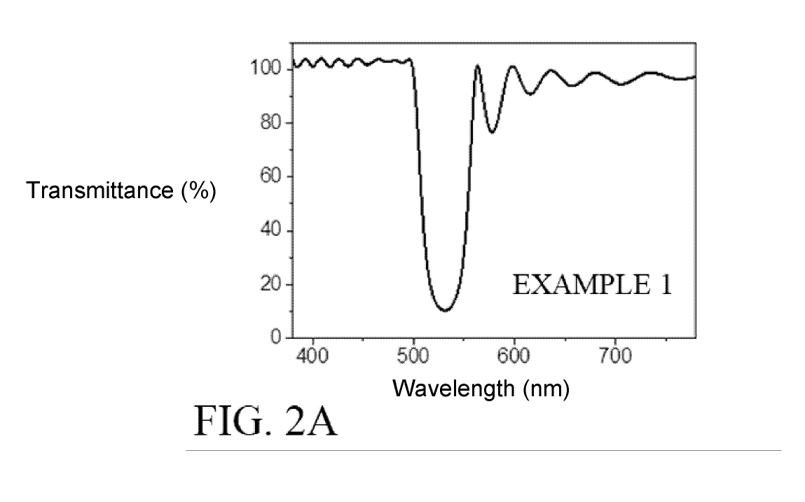

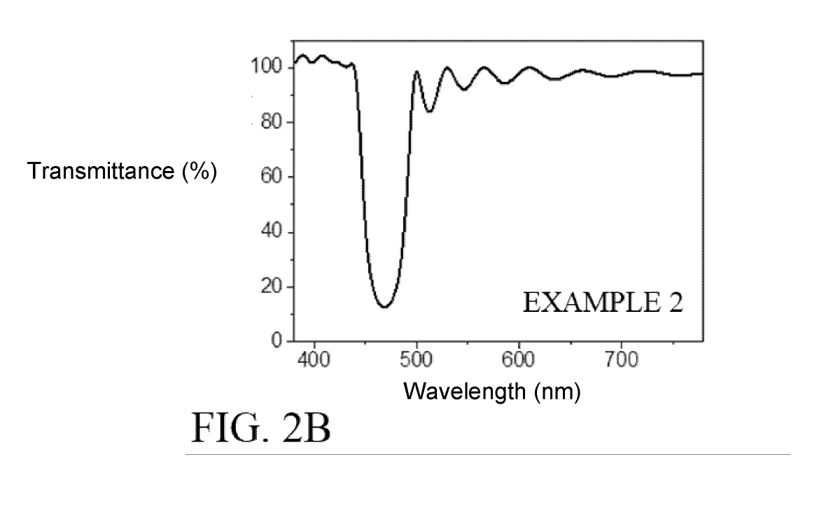

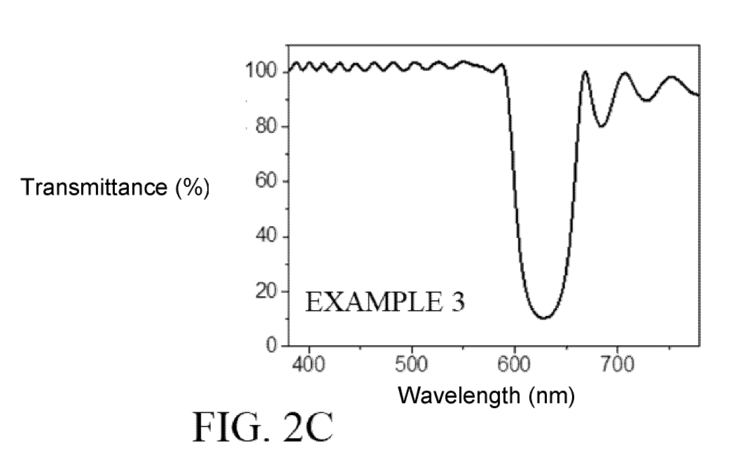

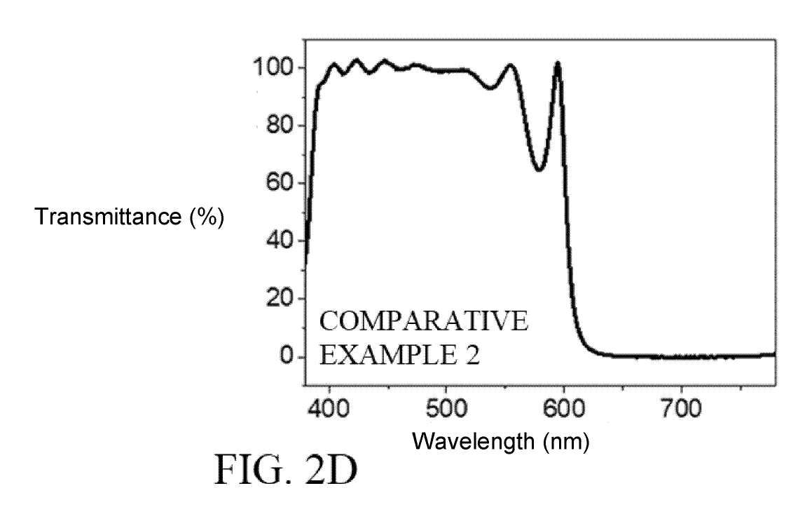

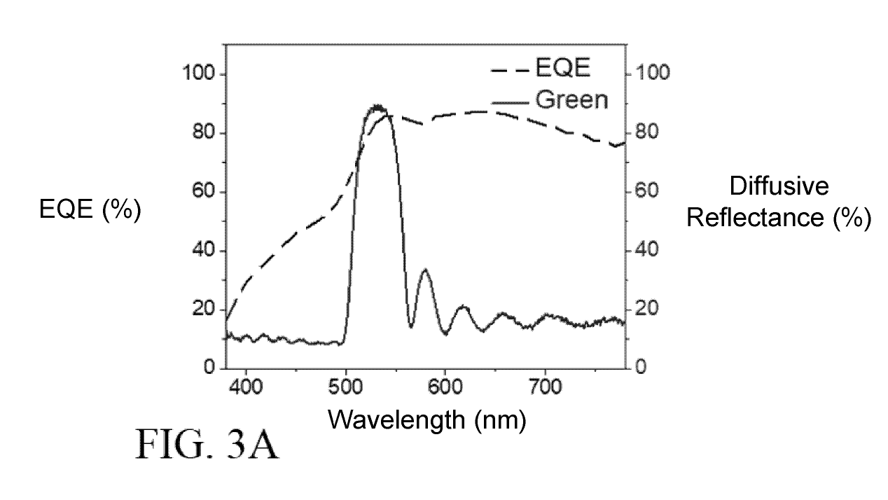

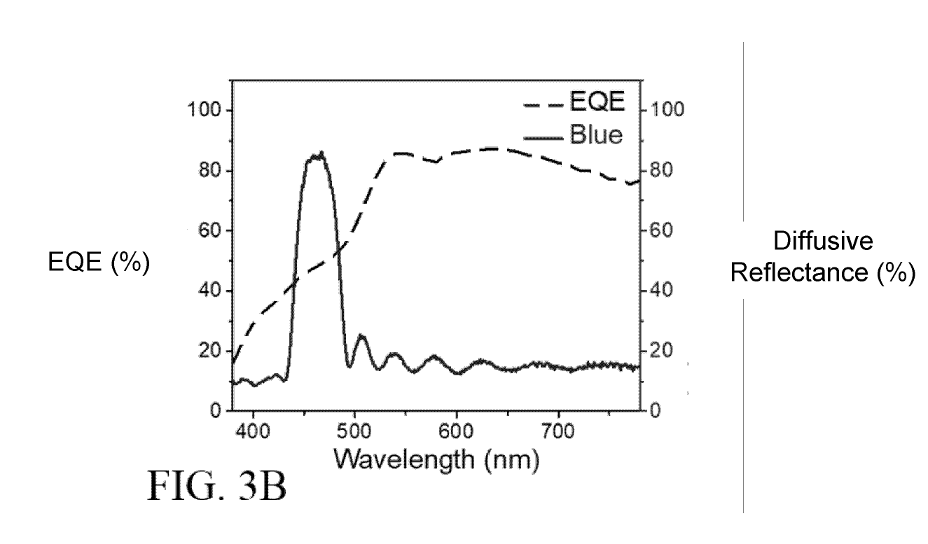

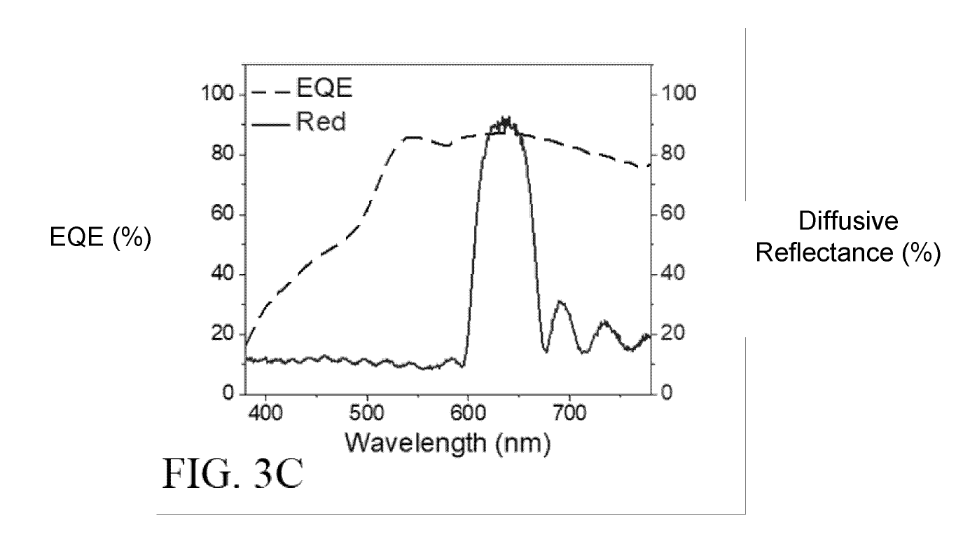

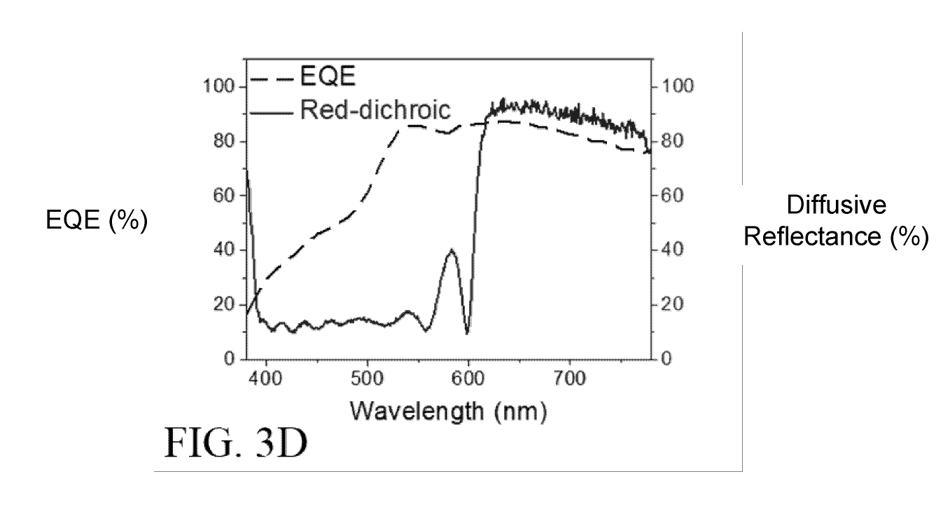

Furthermore, the present invention has an effect in which the above-described vividly changed color of high purity can be obtained without a substantial reduction in efficiency of the thin film solar cell. Specifically, FIGS. 2A to 2C are graphs of transmittance spectra of the green, blue, and red band-stop filters provided at the colored thin film solar cell according to one preferred embodiment of the present invention. As shown in the drawings, the colored thin film solar cell of the present invention may have the above-described band-stop filters to reflect light of a desired wavelength region and transmit the light of the remaining wavelength region, thereby minimizing reduction of efficiency of the thin film solar cell. Further, FIGS. 3A to 3C are graphs illustrating external quantum efficiency (EQE) spectra and diffusive reflectance spectra of the colored thin film solar cell having the green, blue, and red band-stop filters according to one preferred embodiment of the present invention. Looking at the drawings, it can be seen that efficiency of the thin film solar cell may be excellently maintained and a change of color of high purity may be possible at the same time.

Further, each of the band-stop filters of the present invention has a reflective band half width in a range of 100 nm or less. The half width may preferably be in a range of 70 nm or less, more preferably be in a range of 50 nm or less, and most preferably be 30 nm. Since a specific wavelength region of an externally emitted light is reflected and the remaining wavelength region thereof is transmitted as a reflective band half width becomes narrow, a change to a more distinct color is possible. Further, since only a desired specific wavelength region is reflected, there is an effect in that reduction of efficiency of the thin film solar cell may be minimized. Consequently, in the colored thin film solar cell of the present invention, it is possible to exhibit various colors of high purity in addition to blue colors and minimize the reduction of efficiency of the thin film solar cell at the same time.

When half widths of reflective bands of the band-stop filters exceeds the above-described ranges, light of a broad wide wavelength region is reflected such that problems may occur in that color purity is deteriorated due to a mixture of various colors, a distinct color is difficult to exhibit, and light harvesting efficiency is significantly deteriorated when a color of light is changed into colors that are not blue colors.

Further, each of the band-stop filters may be configured such that a first layer, a second layer, and a third layer are alternately stacked, and the stacked first-second-third layers are repeatedly stacked n times, a refractive index of the second layer may be different from that of the first layer, and a refractive index of the third layer may be equal to or different from that of the first layer. That is, each of the band-stop filters may have a structure in which thin films made of different refractive index materials are repeated and may change a color of light by controlling a difference between refractive indexes to reflect the light in only a desired color range.

According to one preferred embodiment of the present invention, a refractive index of each of the first layer and the third layer may be in a range of 1.2 to 1.6, and a refractive index of the second layer may be in a range of 1.4 to 1.8. A specific wavelength region in a narrow band may be reflected by controlling a refractive index such that, as described above, a change to a distinct color of high purity is possible, and the reduction of efficiency of the thin film solar cell may be minimized.

When the refractive indexes of the first layer, the second layer, and the third layer are out of the above-described refractive index ranges, the half widths of the reflective bands of the band-stop filters employed in the colored thin film solar cell of the present invention are excessively widened, such that problems may occur in that color purity is deteriorated, a distinct color is difficult to exhibit, and light harvesting efficiency is significantly deteriorated when a color of light is visually changed into colors that are not blue colors.

Further, the first layer and the third layer of each of the band-stop filters may include SiO₂, and the second layer may include Al₂O₃. A conventional multi-layered filter included in a thin film solar cell and used for a visual color change is configured by repeatedly stacking high and low refractive index materials. However, each of the band-stop filters of the present invention has a multi-layered structure, and the first layer and the third layer include SiO₂ and the second layer includes Al₂O₃, such that a difference in refractive index between materials of the first, second, and third layers is significantly small. Accordingly, since the reflective band half width is narrow, most of externally emitted light are transmitted and a specific partial wavelength region thereof is reflected such that there is an effect in that a black color of a thin film solar cell may be visually changed into various colors. In this case, desired colors of reflected light and transmitted light are controllable in a range of a visible light region, that is, a violet color, a blue color, a yellow color, an orange color, and a red color, and thus the black color of the thin film solar cell may be visually changed into various colors in addition to blue colors.

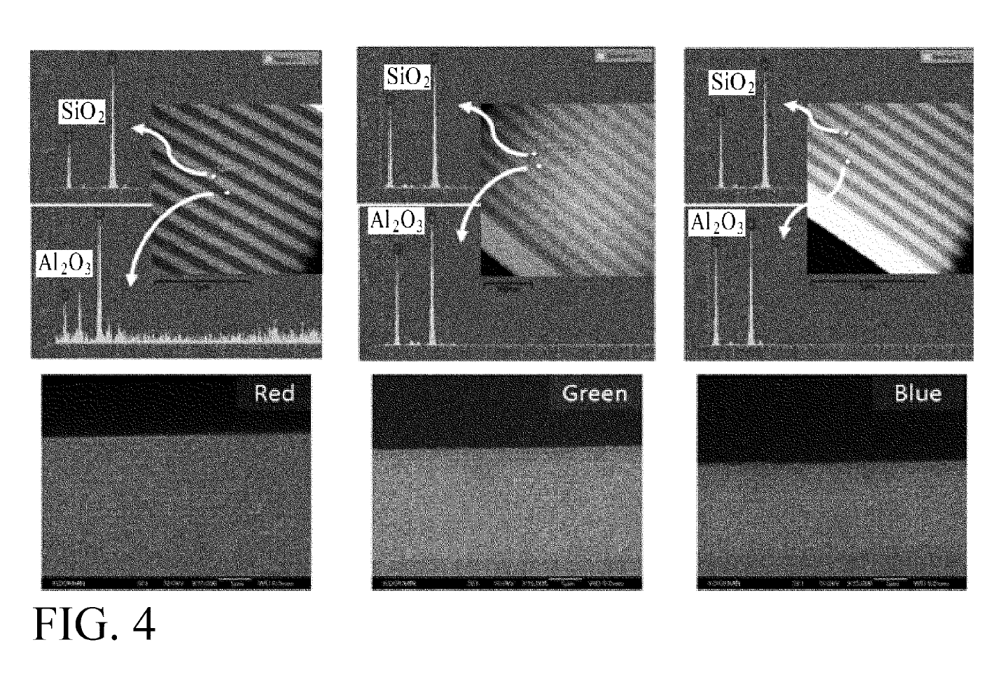

Specifically, FIG. 4 is scanning electron microscope (SEM) cross-sectional images of the red, green, and blue band-stop filters manufactured according to one preferred embodiment of the present invention. Referring to FIG. 4, it can be seen that a SiO₂ layer and a Al₂O₃ layer are alternately stacked.

Further, when the first, second, and third layers are alternately stacked, they may be repeatedly stacked 3 to 25 times with a repetition unit of [first-second-third layer], preferably may be repeatedly stacked 10 to 23 times, and more preferably may be repeatedly stacked 15 to 21 times. As described above, when the repetition unit is repeatedly stacked to form the multilayered band-stop filters, a specific wavelength region of a desired color of light is reflected with high reflectance and the remaining wavelength region of the light is transmitted with high transmittance such that there are effects in that a change to a distinct color can be achieved, a color of high purity can be exhibited, and a color change into various colors of visible light, such as a blue color, a green color, a violet color, a red color, a yellow color, and the like can be attained with only a slight reduction of light harvesting efficiency.

When the first layer, the second layer, and the third layer does not satisfy the above-described range, transmittance and reflectance are deteriorated such that problems may occur in that a desired change to a distinct color of high purity is difficult and the light harvesting efficiency is significantly deteriorated when a color of light is visually changed into colors that are not green, blue, and red colors.

The transmittance and reflectance may be controlled according to a variation in layering of the band-stop filters of the present invention such that a change to a distinct color of high purity can be achieved by reflecting a specific wavelength region of a desired color.

Specifically, a thickness of each of the first to third layers and a thickness ratio thereof may be different according to a desired color, and when the thickness of each of the first to third layers becomes thicker going from a blue color line to a red color line, a change to a distinct color of high purity is possible with only a slight reduction of light harvesting efficiency.

That is, according to one preferred embodiment of the present invention, each of the band-stop filters may have a structure of [0.5SiO₂/Al₂O₃/0.5SiO₂]ⁿ or [0.5Al₂O₃/SiO₂/0.5Al₂O₃]ⁿ, wherein n may be a repetition number of the repetition unit in a range of 3 to 25.

Meanwhile, a thickness of each of the band-stop filters can satisfy the above described range but is not limited as long as each of the band-stop filters can reflect a portion of externally emitted light and transmit the remaining portion thereof while visually changing the color. Preferably, however, the thickness of each of the first layer and the third layer may be in a range of 20 to 100 nm, and the thickness of the second layer may be in a range of 35 to 200 nm. More preferably, the thickness of each of the first layer and the second layer may be in a range of 30 to 75 nm, and the thickness of the second layer may be in a range of 50 to 150 nm. When the thicknesses satisfy the above-described ranges, there is an advantage in that a change to a more distinct color is possible.

According to one embodiment of the present invention, reflectance of each of the band-stop filters may be 60% or more at a central reflection wavelength thereof. When the reflectance of each of the band-stop filters is less than 60%, the reduction of efficiency of the thin film solar cell may be minimized, but the objective of the present invention may not be achieved since a change to a color of high purity is difficult to implement.

As described above, the colored thin film solar cell of the present invention may change a color of a thin film solar cell into various colors by controlling a reflective band. Further, according to one preferred embodiment of the present invention, the band-stop filters may visually change the color of the thin film solar cell into one color of a blue color, a green color, and a red color.

There is no limitation on a type of a band-stop filter employed in the colored thin film solar cell of the present invention as long as the band-stop filter can visually change a black color of the thin film solar cell into various colors by being provided on one surface of the thin film solar cell, and the band-stop filter may be applied to various solar cells such as a perovskite solar cell, a copper indium gallium selenide (CIGS) solar cell, a silicon solar cell, and the like.

Further, the present invention provides a colored thin film solar cell including one or more band-stop filters and satisfies the following conditions (a) and (b).

(a) A reflective band half width of each of the one or more band-stop filters is in a range of 100 nm or less.

(b) The following relational expression 1 is satisfied.

$$0.80 \leq \frac{A}{B} \leq 1.00$$

Here, A is light harvesting efficiency when one or more band-stop filters, each having a reflective band half width of 100 nm or less, are employed, and B is light harvesting efficiency when the one or more band-stop filters are not employed.

Hereinafter, a detailed description will be made excluding that which repeats the above descriptions.

More preferably, A/B may be in a range of 0.85 to 1.00. When A/B is in the above-described range, there may be substantially no reduction in the efficiency of the thin film solar cell, and further, the black color of the thin film solar cell may be visually changed into an aesthetically pleasing color to exhibit an exterior appearance having the aesthetically pleasing color.

That is, half widths of reflective bands of the one or more band-stop filters included in the present invention may be in a range of 100 nm or less, and thus only a specific wavelength region may be reflected with high reflectance, such that a change to a distinct color is possible. Simultaneously, the above-described relational expression 1 is satisfied such that there is an effect in that the black color of the thin film solar cell may be visually changed into an aesthetically pleasing color to exhibit an exterior appearance having the aesthetically pleasing color without substantially lowering the efficiency of the thin film solar cell.

The colored thin film solar cell of the present invention may further satisfy the following condition (c).

$$0.80 \leq \frac{C}{D} \leq 1.00 , \qquad [ Relational Expression 2 ]$$

In the relational expression 2, C is a short circuit current density J_{sc} when one or more band-stop filters, each having a reflective band half width in a range of 100 nm or less, are employed, and D is a short circuit current density J_{sc} when the one or more band-stop filters are not employed.

C/D may preferably be in a range of 0.80 to 1.00. When C/D is in the above-described range, a utility value may be improved by visually changing the black color of the thin film solar cell into an aesthetically pleasing color to exhibit an exterior appearance having the aesthetically pleasing color while the short circuit current density J_{sc} is maintained. When C/D is less than 0.80, a visual color change of the exterior appearance of the thin film solar cell may be possible, but a problem in that the efficiency of the thin film solar cell is lowered may occur.

The present invention provides the exterior including one of the above-described colored thin film solar cells. Further, the colored thin film solar cell of the present invention may be used as the exterior or the interior of a building.

Here, use in the exterior of a building includes a case in which the colored thin film solar cell is utilized as a finishing material of a building envelope using the BIPV (Building Integrated Photovoltaic) technique, as well a case in which the colored thin film solar cell is utilized in windows and doors. Further, the colored thin film solar cell may be utilized in the interior of a building to exert decoration effect in the interior.

As a result, the present invention can be valuably utilized for not only an exterior appearance of a building but also interior decoration thereof, thereby having various utility values and compatibility.

Hereinafter, examples of the present invention will be described. However, the scope of the present invention is not limited to these examples.

### Example 1

(1) Manufacture of CIGSSe Solar Cell

A solar cell element was manufactured according to a conventional structure of substrate/first rear surface electrode/second rear surface electrode/CIGSSe/CdS/i-ZnO/n-ZnO. A CIGSSe light absorption layer was manufactured using a solution-based method. A CdS buffer layer having a thickness of 60 nm was formed on the CIGSSe light absorption layer by chemical bath deposition (CBD), and the n-ZnO layer (having a thickness of 500 nm) doped with Al was deposited with i-ZnO (having a thickness of 50 nm) by magnetron sputtering.

(2) Manufacture and Preparation of Green Band-Stop Filter

A green band-stop filter was manufactured on a glass substrate. To design the green band-stop filter, reflectance (R), transmittance (T), and absorption (A) was simulated using a characteristic matrix method. The green band-stop filter was configured such that a SiO₂ layer (having a thickness of 43.7 nm) and a Al₂O₃ layer (having a thickness of 84.7 nm) were applied on the glass substrate and alternately stacked thereon using an electron-beam evaporator to form a structure of [0.5 SiO₂/Al₂O₃/0.5SiO₂] ¹⁸.

The green band-stop filter coated on the glass substrate was provided at an upper surface of the CIGSSe solar cell to manufacture a colored thin film solar cell.

### Example 2

Example 2 was implemented similar to Example 1, but a red band-stop filter was manufactured such that a SiO₂ layer (having a thickness of 51.3 nm) and a Al₂O₃ layer (having a thickness of 102.5 nm) were alternately stacked on the glass substrate to form a structure of [0.5SiO₂/Al₂O₃/0.5SiO₂]¹⁸, and the red band-stop filter was provided at the upper surface of the CIGSSe solar cell.

### Example 3

Example 3 was implemented similar to Example 1, but a blue band-stop filter was manufactured such that a SiO₂ layer (having a thickness of 39.5 nm) and a Al₂O₃ layer (having a thickness of 71.3 nm) were alternately stacked on the glass substrate to form a structure of [0.5SiO₂/Al₂O₃/0.5SiO₂]¹⁸, and the blue band-stop filter was provided at the upper surface of the CIGSSe solar cell.

### Comparative Example 1

Comparative Example 1 was implemented similar to Example 1, but the band-stop filters were not provided.

### Comparative Example 2

Comparative Example 1 was implemented similar to Example 1, but a dichroic filter was manufactured such that a SiO₂ layer (having a thickness of 62 nm) and a Al₂O₃ layer (having a thickness of 81 nm) were alternately stacked on the glass substrate to form a structure of [0.5SiO₂/TiO₂/0.5SiO₂]⁹, and the dichroic filter was provided at the upper surface of the CIGSSe solar cell.

### Experimental Example 1—Measurement of Transmittance Spectrum and Reflection Spectrum

Transmittance spectra of the band-stop filters manufactured in Examples 1, 2, and 3, and a transmittance spectrum of the dichroic filter manufactured in Comparative Example 2 were measured using the S-3100 system (Manufacturer: Scinco Co. Ltd.), and diffusive reflectance spectra of the band-stop filters, and the dichroic filter were measured using an LS-F100HS apparatus equipped with a 100 W halogen lamp (Manufacturer: PSI).

FIGS. 2A to 2D are graphs illustrating the transmittance spectrum measurement results of the band-stop filters manufactured in Examples 1, 2, and 3, and the dichroic filter manufactured in Comparative Example 2.

Referring to FIGS. 2A to 2C, it can be seen that the green, red, and blue band-stop filters provided at the colored thin film solar cell according to the present invention can transmit light of a broad wavelength region, thereby reflecting light in a desired wavelength region, transmitting light in the remaining wavelength region, and minimizing reduction of efficiency of the CIGSSe solar cell.

On the other hand, as shown in FIG. 2D, it can be seen that light of a wavelength region which is transmittable through the dichroic filter was significantly reduced.

Further, FIGS. 3A to 3D are graphs illustrating the measurement results of EQE spectra and diffusive reflectance spectra of the band-stop filters manufactured in Examples 1, 2, and 3, and the dichroic filter manufactured in Comparative Example 2. Referring to FIGS. 3A to 3C, it can be seen that the colored thin film solar cell according to the present invention has the band-stop filters to thereby excellently maintain light harvesting efficiency and simultaneously have a narrow reflective band half width and reflectance of 60% or more in a central reflection wavelength, such that a change to a color of high purity is possible.

Meanwhile, as shown in FIG. 3D, when the dichroic filter is provided, the colored thin film solar cell may cause deterioration of the light harvesting efficiency since a reflective band half width of the dichroic filter is large.

### Experimental Example 2—Observation of SEM Images

SEM images of the band-stop filters manufactured in Examples 1, 2, and 3, and the dichroic filter manufactured in Comparative Example 2 were observed using a JSM-7610F apparatus, and the observation results are shown in FIG. 4. Referring to FIG. 4, it can be seen that a SiO₂ layer and an Al₂O₃ layer were alternately stacked to form the respective band-stop filters.

### Experimental Example 3—Measurement of Current Density-Voltage (J-V) and Calculation of Efficiency

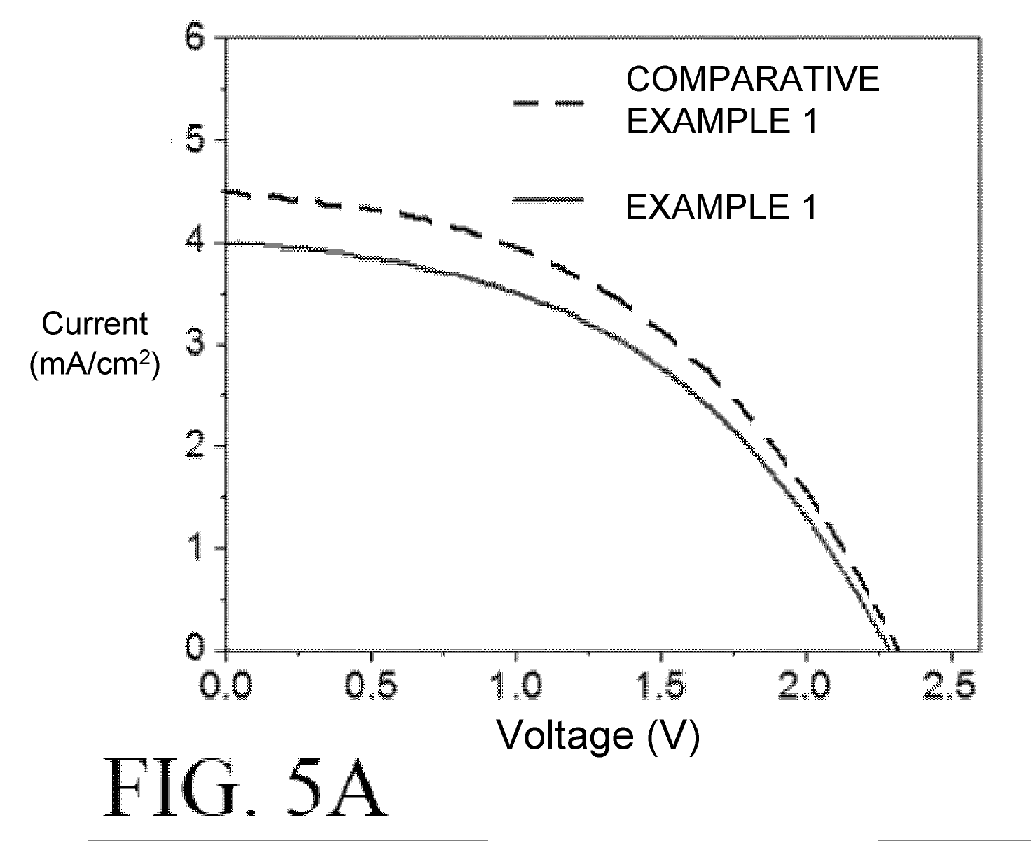

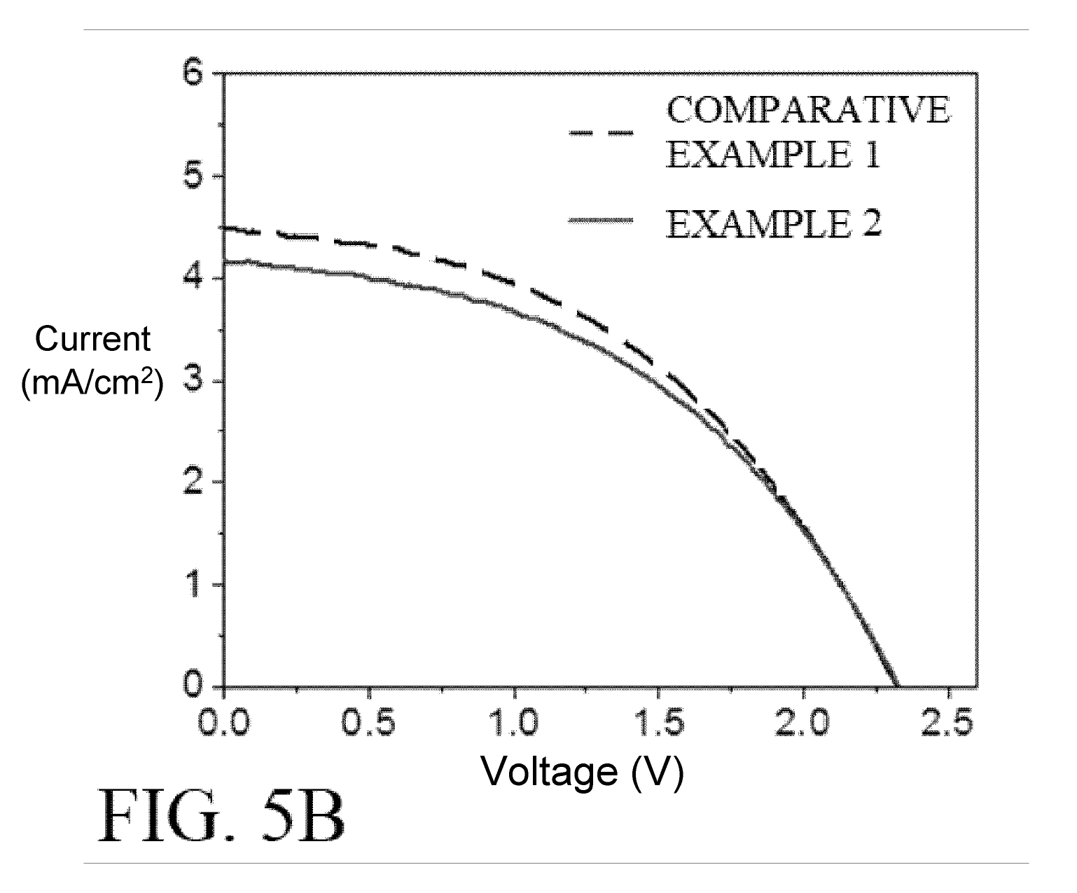

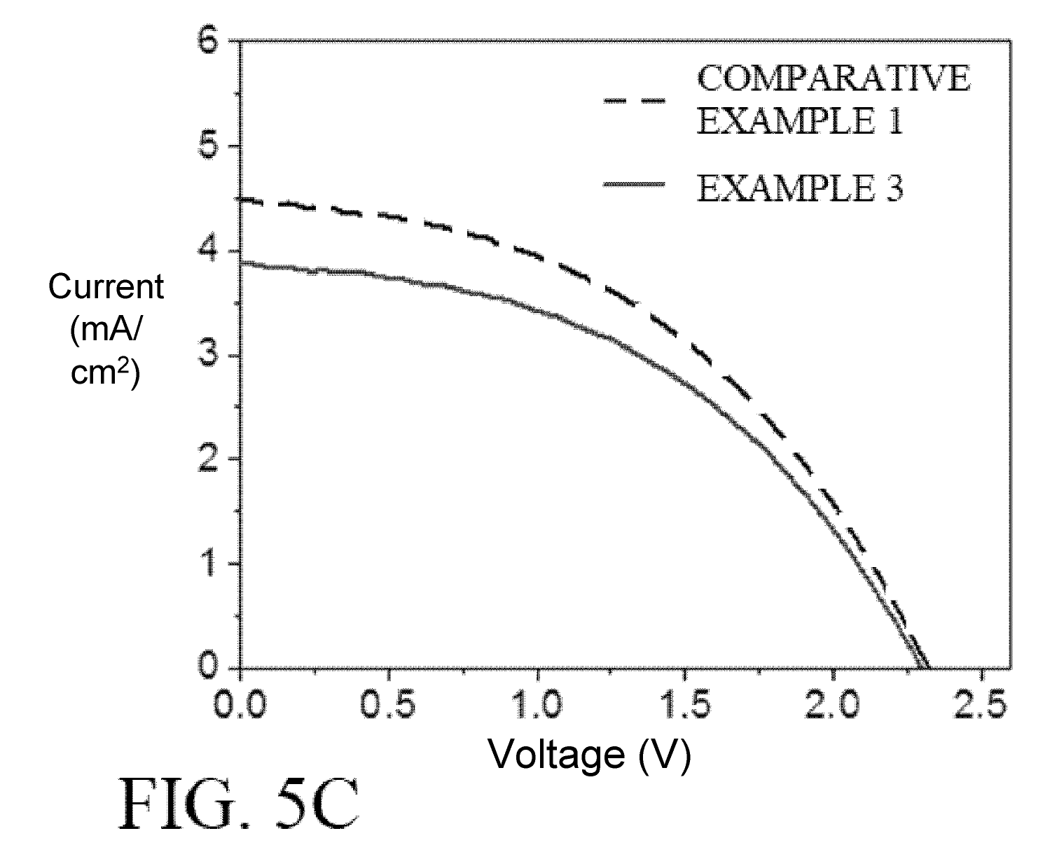

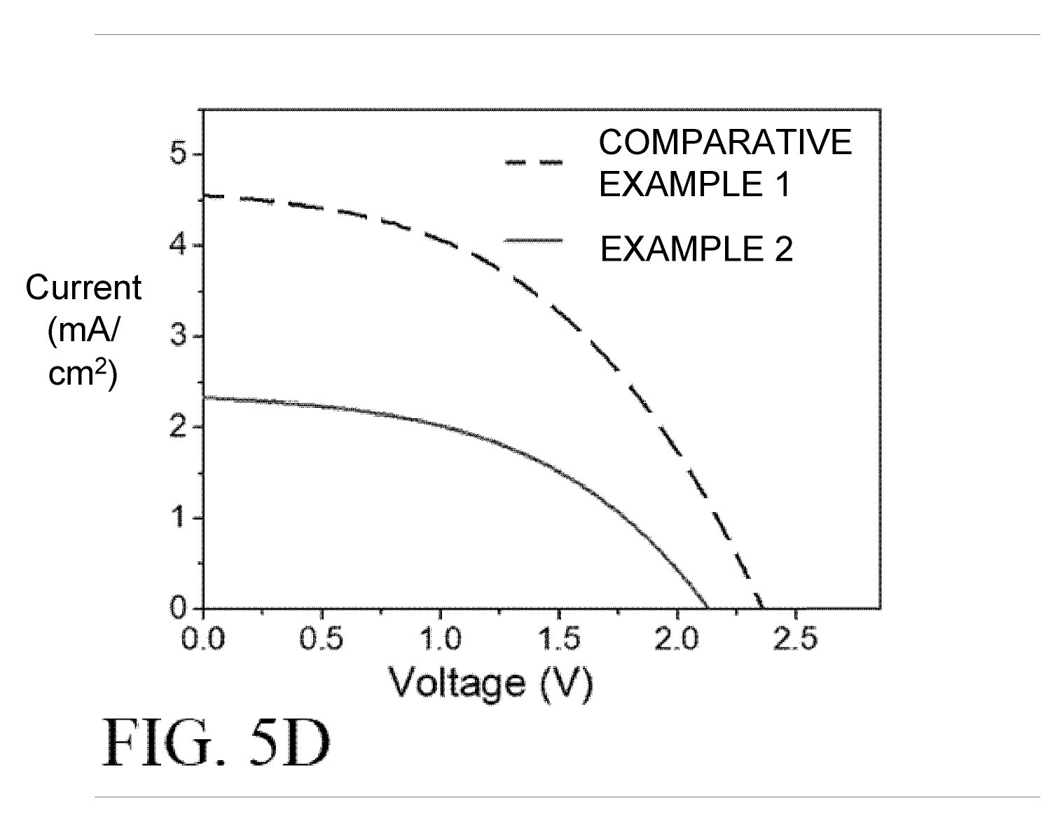

A current density-voltage (J-V) of the colored thin film solar cells manufactured in Examples 1, 2, and 3, and Comparative Examples 1 and 2 was measured using Keithley 2401 equipped with a 150-watt (W) xenon lamp (Manufacturer: Newport Co.). A light source was calibrated by a KG-5 filter, all the J-V measurements were performed under sunlight condition, and the measurement results are shown in FIGS. 5A to 5D.

An open circuit voltage Voc, a short circuit current density Jsc, and a fill factor FF of each of the CIGSSe thin film solar cells, which were manufactured in Examples 1, 2, and 3 and Comparative Examples 1 and 2, were measured and an efficiency and a relative efficiency A/B of solar cell were calculated to be shown in the following Table 1.

TABLE 1

| | Half | | | | | |
|---|---|---|---|---|---|---|
| | width | Voc | Jsc | FF | Eff | |
| | (nm) | (V) | (mA/cm2) | (%) | (%) | A/B |
| Example 1 | 50 | 2.30 | 4.05 | 0.46 | 4.28 | 0.87 |
| Example 2 | 50 | 2.26 | 3.96 | 0.46 | 4.08 | 0.83 |
| Example 3 | 50 | 2.38 | 4.22 | 0.46 | 4.66 | 0.95 |
| Comparative | — | 2.36 | 4.55 | 0.46 | 4.91 | 1.00 |
| Example 1 | | | | | | |
| Comparative | — | 2.13 | 2.33 | 0.46 | 2.31 | 0.47 |
| Example 2 | | | | | | |

* A/B is a ratio of light harvesting efficiency of the colored thin film solar cell to the solar cell according to Comparative Example 1 in which the band-stop filters were not provided.

Table 1 shows the measurement results of efficiencies of the thin film solar cells manufactured in Examples 1 to 3 and Comparative Examples 1 and 2. As can be seen from Table 1, light harvesting efficiencies and Jsc of the colored thin film solar cells manufactured in Examples 1 to 3 according to the present invention were kept substantially similar to those of a conventional black colored thin film solar cell (Comparative Example 1), and fill factors FF thereof were also kept substantially similar to that of the conventional black colored thin film solar cell. That is, it can be seen that the efficiency of the colored thin film solar cell according to the present invention may not be substantially reduced and the black color thereof may also be visually changed into an aesthetically pleasing color of reflected light.

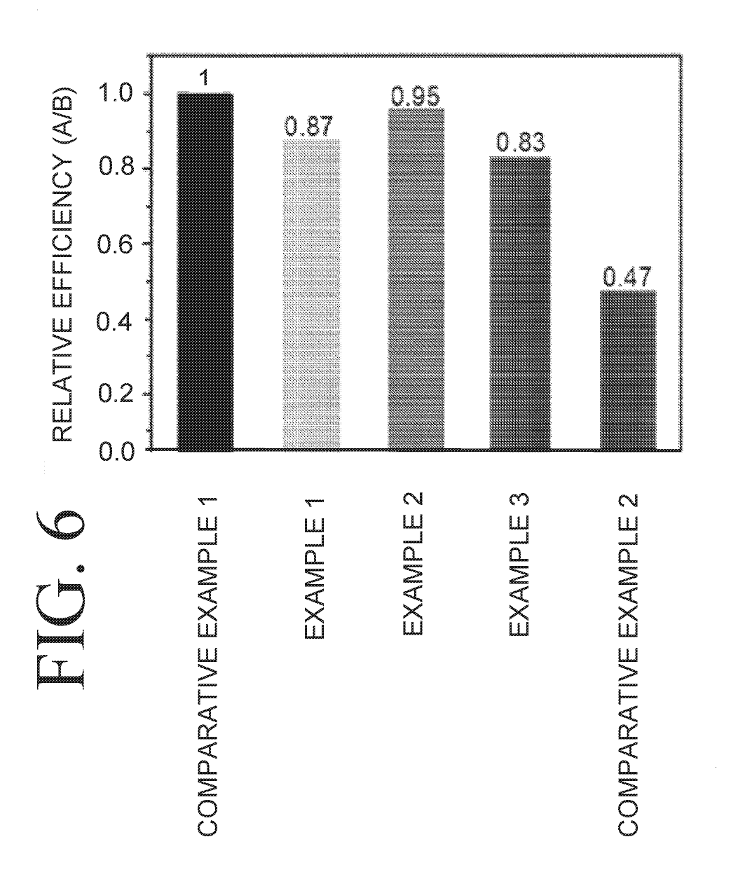

Further, referring to FIG. 6, it can be seen that the light harvesting efficiency was reduced by no greater than 17% even when the blue, green, and red colored thin film solar cells were manufactured.

On the other hand, it can be seen that the light harvesting efficiency of the solar cell having the conventional dichroic filter according to Comparative Example 2 was reduced to 47%.

Therefore, it can be seen that the colored thin film solar cell according to the present invention can change a color into various colors without a substantial reduction in efficiency of the thin film solar cell by providing a band-stop filter, and thus it can be widely used in outer walls or the interior of a building.

As described above, the present invention provides a colored thin film solar cell capable of preventing or minimizing reduction of efficiency of a thin film solar cell and improving a utility value for application to the exterior or the interior of a building by visually changing a black color of the thin film solar cell into an aesthetically pleasing color to exhibit an exterior appearance, thereby facilitating commercialization of the thin film solar cell, and provides a method for manufacturing the same.

Further, the colored thin film solar cell of the present invention can visually change a black color of a thin film solar cell into an aesthetically pleasing color, even when used for application to a finishing material of a building envelope or the interior of a building, with only a slight reduction in light harvesting efficiency and short circuit current density, thereby being able to be widely utilized in a BIPV technique field.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A colored thin film solar cell comprising:
a solar cell; and
a band-stop filter provided on one surface of the solar cell, configured to reflect a portion of externally emitted light and transmit the remaining portion thereof to thereby visually change a color of the solar cell,
wherein the band-stop filter is configured such that a first layer, a second layer, and a third layer are alternately stacked, and a repetition unit of the first-second-third layers is repeatedly stacked, wherein the refractive index of each of the first layer and the third layer is in a range of 1.2 to 1.6, and the refractive index of the second layer is in a range of 1.4 to 1.8,
wherein each of the first layer and the third layer includes SiO₂, and the second layer includes Al₂O₃,
wherein the colored thin film solar cell satisfies conditions (a) and (b):
(a) The band-stop filter has a reflective band half width in a range of 100 nm or less, and
(b) A relational expression 1 is satisfied as follows,
$$0.80 \leq \frac{A}{B} \leq 1.00 , \qquad [ Relational Expression 1 ]$$
wherein, A is light harvesting efficiency when one or more band-stop filters, each having a reflective band half width in a range of 100 nm or less, are employed, and B is light harvesting efficiency when the one or more band-stop filters are not employed.

2. The colored thin film solar cell of claim 1, wherein the half width is in a range of 70 nm or less.

3. (canceled)

4. (canceled)

5. (canceled)

6. The colored thin film solar cell of claim 1 wherein n is in a range of 3 to 25.

7. The colored thin film solar cell of claim 1, wherein the band-stop filter visually changes a color of the solar cell into one of a blue color, a green color, a yellow color, a purple color, and a red color.

8. The colored thin film solar cell of claim 1, wherein the band-stop filter has a reflectance of 60% or more at a central reflection wavelength thereof.

9. The colored thin film solar cell of claim 1, wherein the solar cell is a perovskite solar cell, a copper indium gallium selenide (CIGS) solar cell, or a silicon solar cell.

10. (canceled)

11. The colored thin film solar cell of claim 1, further satisfying a condition (c):
(c) A relational expression 2 is satisfied as follows,
$$0.80 \leq \frac{C}{D} \leq 1.00 , \qquad [ Relational Expression 2 ]$$
wherein C is a short circuit current density J_{sc} when the one or more band-stop filters, each having a reflective band half width in a range of 100 nm or less, are employed, and D is a short circuit current density J_{sc} when the one or more band-stop filters are not employed.

12. An exterior including the colored thin film solar cell according to claim 1.
